(19) United States
(12) Patent Application Publication
(10) Pub. No.: US 2024/0413115 A1
(43) Pub. Date: Dec. 12, 2024

(54) PACKAGE STRUCTURE

(71) Applicant: Advanced Semiconductor Engineering, Inc., Kaohsiung (TW)

(72) Inventors: Yu-Ling YEH, Kaohsiung (TW); Yuan-Feng CHIANG, Kaohsiung (TW); Chung-Hung LAI, Kaohsiung (TW); Chin-Li KAO, Kaohsiung (TW)

(73) Assignee: Advanced Semiconductor Engineering, Inc., Kaohsiung (TW)

(21) Appl. No.: 18/207,090

(22) Filed: Jun. 7, 2023

(51) Int. Cl. H01L 23/00; H01L 23/31

(52) U.S. Cl. CPC H01L 24/24; H01L 23/3128; H01L 2224/24011; H01L 2224/24051; H01L 2224/244

(57) ABSTRACT

A package structure is provided. The package structure includes an electronic component, an encapsulant, a first conductive pillar, a first dielectric layer. The electronic component has an active surface. The encapsulant encapsulates the electronic component and exposes the active surface of the electronic component. The first conductive pillar is over the active surface of the electronic component, wherein an upper surface of the first conductive pillar includes a concave portion. The first dielectric layer is over the encapsulant and the active surface of the electronic component, wherein the first dielectric layer defines an opening exposing the concave portion of the first conductive pillar.

### BACKGROUND

### 1. Field of the Disclosure

The present disclosure relates to a package structure, and particularly to a package structure including a redistribution structure capable of being imposed more stress.

### 2. Description of the Related Art

In a conventional package structure, a redistribution structure may be formed over an electronic component and over an encapsulant. The coefficient of thermal expansion (CTE) between the redistribution structure and the encapsulant may cause a crack, resulting delamination between the redistribution structure and the electronic component. Therefore, a new package structure is required to address the aforesaid issues.

### SUMMARY

In some embodiments, a package structure includes an electronic component, an encapsulant, a first conductive pillar, a first dielectric layer. The electronic component has an active surface. The encapsulant encapsulates the electronic component and exposes the active surface of the electronic component. The first conductive pillar is over the active surface of the electronic component. An upper surface of the first conductive pillar includes a concave portion. The first dielectric layer is over the encapsulant and the active surface of the electronic component. The first dielectric layer defines an opening exposing the concave portion of the first conductive pillar.

In some embodiments, a package structure includes an electronic component and a redistribution structure. The electronic component has an active surface. The redistribution structure is over the active surface of the electronic component. The redistribution structure includes a first dielectric layer over the active surface of the electronic component. The first dielectric layer defines an opening. The redistribution structure also includes a conductive pillar under the opening. The redistribution structure further includes a second dielectric layer over the first dielectric layer. A first thickness of the first dielectric layer is greater than a second thickness of the second dielectric layer.

In some embodiments, a package structure includes a first electronic component, a second electronic component, an encapsulant, and a first dielectric layer. The first electronic component includes a first active surface. The second electronic component includes a second active surface. The encapsulant encapsulates the first electronic component and the second electronic component. The first dielectric layer is disposed over the encapsulant and exposes the first active surface and the second active surface. The first dielectric layer includes a concave portion between the first electronic component and the second electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of a package structure according to some embodiments of the present disclosure.

FIG. 2A illustrates a cross-sectional view of an example of a package structure according to some embodiments of the present disclosure.

FIG. 2B illustrates a partial enlarged view of the package structure as shown in FIG. 2A according to some embodiments of the present disclosure.

FIG. 3 illustrates a cross-sectional view of an example of a package structure according to some embodiments of the present disclosure.

FIG. 4 illustrates a cross-sectional view of an example of a package structure according to some embodiments of the present disclosure.

FIG. 5 illustrates a cross-sectional view of an example of a package structure according to some embodiments of the present disclosure.

FIG. 6 illustrates a cross-sectional view of an example of a package structure according to some embodiments of the present disclosure.

FIG. 7 illustrates a cross-sectional view of an example of a package structure according to some embodiments of the present disclosure.

FIG. 8 illustrates a cross-sectional view of an example of a package structure according to some embodiments of the present disclosure.

FIG. 9 illustrates a cross-sectional view of an example of a package structure according to some embodiments of the present disclosure.

FIG. 10 illustrates a cross-sectional view of an example of a package structure according to some embodiments of the present disclosure.

FIG. 11 illustrates a cross-sectional view of an example of a package structure according to some embodiments of the present disclosure.

FIG. 12 illustrates a cross-sectional view of an example of a package structure according to some embodiments of the present disclosure.

FIG. 13 illustrates a cross-sectional view of an example of a package structure according to some embodiments of the present disclosure.

FIG. 14 illustrates a cross-sectional view of an example of a package structure according to some embodiments of the present disclosure.

FIG. 15 illustrates a cross-sectional view of an example of a package structure according to some embodiments of the present disclosure.

FIG. 16 illustrates a cross-sectional view of an example of a package structure according to some embodiments of the present disclosure.

FIG. 17A illustrates one or more stages of an example of a method for manufacturing a package structure according to some embodiments of the present disclosure.

FIG. 17B illustrates one or more stages of an example of a method for manufacturing a package structure according to some embodiments of the present disclosure.

FIG. 17C illustrates one or more stages of an example of a method for manufacturing a package structure according to some embodiments of the present disclosure.

FIG. 17D illustrates one or more stages of an example of a method for manufacturing a package structure according to some embodiments of the present disclosure.

FIG. 17E illustrates one or more stages of an example of a method for manufacturing a package structure according to some embodiments of the present disclosure.

FIG. 18A illustrates one or more stages of an example of a method for manufacturing a package structure according to some embodiments of the present disclosure.

FIG. 18B illustrates one or more stages of an example of a method for manufacturing a package structure according to some embodiments of the present disclosure.

FIG. 18C illustrates one or more stages of an example of a method for manufacturing a package structure according to some embodiments of the present disclosure.

FIG. 18D illustrates one or more stages of an example of a method for manufacturing a package structure according to some embodiments of the present disclosure.

FIG. 19A illustrates one or more stages of an example of a method for manufacturing a package structure according to some embodiments of the present disclosure.

FIG. 19B illustrates one or more stages of an example of a method for manufacturing a package structure according to some embodiments of the present disclosure.

FIG. 19C illustrates one or more stages of an example of a method for manufacturing a package structure according to some embodiments of the present disclosure.

FIG. 19D illustrates one or more stages of an example of a method for manufacturing a package structure according to some embodiments of the present disclosure.

Common reference numerals are used throughout the drawings and the detailed description to indicate the same or similar components. Embodiments of the present disclosure will be readily understood from the following detailed description taken in conjunction with the accompanying drawings.

### DETAILED DESCRIPTION

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

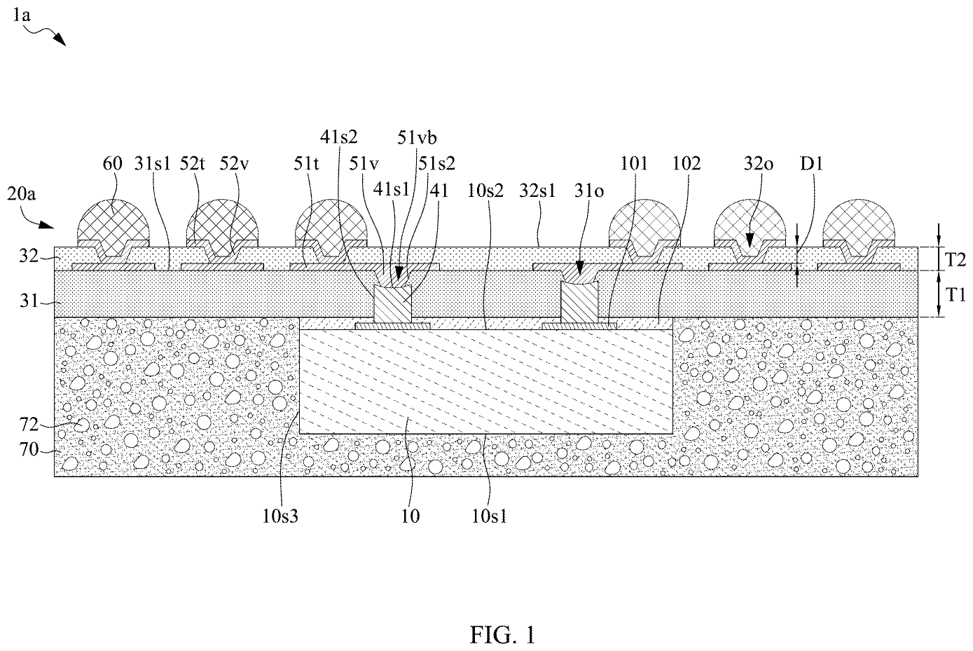

FIG. 1 illustrates a cross-sectional view of an example of a package structure 1a according to some embodiments of the present disclosure. In some embodiments, the package structure 1a may include an electronic component 10, a redistribution structure 20a, a plurality of electrical connectors 60, and an encapsulant 70.

The electronic component 10 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 10 may include a system on chip (SoC). For example, the electronic component 10 may include a radiofrequency IC (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. The electronic component 10 may have a surface 10s1 (or a lower surface) and a surface 10s2 (or an upper surface) opposite to the surface 10s1. The surface 10s1 may function as a backside surface. The surface 10s2 may function as an active surface through which a signal or a power pass. The electronic component 10 may include a surface 10s3 (or a laterals surface) extending between the surfaces 10s1 and 10s2. The surface 10s3 may also be regarded as an interface between the electronic component 10 and other components (e.g., encapsulant 70).

The electronic component 10 may include terminals 101 and a passivation layer 102 over the surface 10s2. The terminal 101 may include a conductive pad or other suitable elements. The passivation layer 102 may cover the surface 10s2 of the electronic component 10. The passivation layer 102 may cover the terminals 101. The passivation layer 102 may include a dielectric layer(s), such as polybenzoxazoles (PBO), or other suitable materials.

The redistribution structure 20a may be disposed over the surface 10s2 of the electronic component 10. The redistribution structure 20a may be configured to electrically connect the electronic component 10 and the electrical connectors 60. The redistribution structure 20a may be configured to transmit a power to the electronic component 10 or transmit a signal toward or from the electronic component 10. In some embodiments, the redistribution structure 20a may include a dielectric layer 31, a dielectric layer 32, a conductive pillar 41, a circuit layer 51t, a conductive via 51v, a circuit layer 52t, and a conductive via 52v.

The dielectric layer 31 may be disposed over the surface 10s2 of the electronic component 10. The dielectric layer 31 may be disposed over the encapsulant 70. In some embodiments, the dielectric layer 31 may be in contact with the passivation layer 102. In some embodiments, the dielectric layer 31 may be in contact with an interface between the encapsulant 70 and the passivation layer 102. The dielectric layer 31 may include, for example, a polyimide or other dielectric suitable materials. The dielectric layer 31 may define openings 310, each of which may be defined by a tapered sidewall of the dielectric layer 31. The conductive pillar 41 may be disposed under the openings 310. Each of the openings 310 may expose the concave portion 41s1 of the conductive pillar 41. Each of the openings 310 may be configured to accommodate the conductive via 51v. The dielectric layer 31 may have a surface 31s1 (or an upper surface) spaced apart from the electronic component 10 and/or the encapsulant 70. The dielectric layer 31 may have a thickness T1.

The conductive pillar 41 may be disposed over the surface 10s2 of the electronic component 10. In some embodiments, the conductive pillar 41 may penetrate the passivation layer 102. The conductive pillar 41 may be electrically connected to the terminal 101. The conductive pillar 41 may include, for example, copper, aluminum, titanium, another conductive metal, or an alloy thereof. The conductive pillar 41 may have a surface 41s1 (or an upper surface) and a surface 41s2 (or a lateral surface). In some embodiments, the surface 41s1 may be or include a concave surface (or a concave portion). For example, the surface 41s1 of the conductive pillar 41 may have a center with an elevation lower than an elevation of an edge. In some embodiments, the surface 41s1 of the conductive pillar 41 may be at least partially lower than the surface 31s1 of the dielectric layer 31. In some embodiments, a portion of the surface 41s1 of the conductive pillar 41 may be covered by the dielectric layer 31. In some embodiments, the surface 41s2 may be substantially orthogonal to and protrude from the surface 10s1 of the electronic component 10. In some embodiments, the surface 41s1 of the conductive pillar 41 may be closer to the surface 31s1 of the dielectric layer 31 than to the surface 10s2 of the electronic component 10. In some embodiments, the dielectric layer 31 may extend into the concave portion (e.g., 41s1) of the conductive pillar 41.

In some embodiments, the conductive via 51v may be disposed over and connected to the conductive pillar 41. In some embodiments, the conductive via 51v may be connected to the concave portion (e.g., 41s1) of the conductive pillar 41. In some embodiments, the conductive via 51v may be located within the opening 310 of the dielectric layer 31. In some embodiments, the conductive via 51v may have an aperture (or a diameter) less than that of the conductive pillar 41 at the interface between the conductive via 51v and the conductive pillar 41. In some embodiments, a portion of the conductive pillar 41 may be exposed from the conductive via 51v. In some embodiments, a portion (e.g., the edge portion) of the surface 41s1 of the conductive pillar 41 is higher than the bottom 51vb of the conductive via 51v. In some embodiments, the conductive via 51v may laterally overlap a portion of the conductive pillar 41. A surface 51s2 (or a lateral surface), extending between the surface 31s1 of the dielectric layer 31 and the surface 41s1 of the conductive pillar 41, of the conductive via 51 may be steeper than the surface 41s2 (or a lateral surface) of the conductive pillar 41.

The circuit layer 51t may be disposed over the surface 31s1 of the dielectric layer 31. The circuit layer 51t may be connected to the conductive via 51v. In some embodiments, the circuit layer 51t may extend continuously across over the interface (not annotated) between the passivation layer 102 of the electronic component 10 and the encapsulant 70. In some embodiments, the conductive via 51v and the circuit layer 51t may be a monolithic structure, which may be formed by the same process, such as the same deposition process (e.g., sputter deposition).

The dielectric layer 32 may be disposed over the surface 31s1 of the dielectric layer 31. The dielectric layer 32 may cover the circuit layer 51t. In some embodiments, the dielectric layer 32 may be in contact with the dielectric layer 31. The dielectric layer 32 may include, for example, a polyimide or other dielectric suitable materials. The dielectric layer 32 may define openings 32o. Each of the openings 32o may expose the circuit layer 51t. Each of the openings 32o may be configured to accommodate the conductive via 52v. The dielectric layer 32 may have a surface 32s1 (or an upper surface) spaced apart from the dielectric layer 31. The dielectric layer 32 may have a thickness T2. In some embodiments, the thickness T1 may be greater than the thickness T2. In some embodiments, the ratio between the thickness T1 and the thickness T2 may be 1.8, 2, 2.2, 2.5, 3, 5, or more.

In some embodiments, the conductive via 52v (or inner via) may be disposed over and connected to the circuit layer 51t. The conductive via 52v may be disposed over the dielectric layer 31. In some embodiments, the conductive via 52v may be located within the opening 32o of the dielectric layer 32. In some embodiments, the conductive via 52v may be conformally formed within the opening 32o of the dielectric layer 32.

The circuit layer 52t may be disposed over the surface 32s1 of the dielectric layer 32. The circuit layer 52t may be connected to the conductive via 52v. In some embodiments, the conductive via 52v and the circuit layer 52t may be a monolithic structure, which may be formed by the same process, such as the same deposition process. The circuit layer 52t and the conductive via 52v may collectively function as an under bump metallization (UBM). The circuit layers 51t and 52t may have a distance D1 defined by the lower surface of the circuit layer 52t and the upper surface of the circuit layer 51t. The distance D1 may also be defined as a depth of the conductive via 52v. In some embodiments, the distance D1 may be less than the thickness T1 of the dielectric layer 31. That is, the thickness T1 of the dielectric layer 31 may be greater than the depth D1 of the conductive via 52v.

The electrical connectors 60 may be disposed over the circuit layer 52t. In some embodiments, the electrical connectors 60 may be configured to electrically connect the package structure 1a to an external device (not shown). Each of the electrical connectors 60 may include electrical contacts, such as solder balls, conductive bumps, or the like. The electrical connectors 60 may include alloys of gold and tin solder or alloys of silver and tin solder.

The encapsulant 70 may encapsulate the electronic component 10. The encapsulant 70 may encapsulate the surface 10s1 of the electronic component 10. The surface 10s2 of the electronic component 10 may be exposed from the encapsulant 70. The encapsulant 70 may have a surface 70s1 (or an upper surface). The redistribution structure 20a may be disposed over the surface 70s1 of the encapsulant 70. For example, the dielectric layer 31 may be disposed over the surface 70s1. The encapsulant 70 may include a Novolac-based resin, an epoxy-based resin, a silicone-based resin, or another suitable material. The encapsulant 70 may include fillers 72, which may include powdered SiO₂.

In a comparative package structure, the lowest dielectric layer of a redistribution structure cannot suffer a relatively large thermal stress, which is caused by a large difference of CTE among different materials. As a result, a delamination occurs between the redistribution structure and an electronic component during a thermal test, which involves multiple cycles of heating and cooling. In this embodiment, the dielectric layer 31, the lowest dielectric layer of the redistribution structure 20a, has a relatively large thickness to function as a buffer layer, thereby reinforcing the lowest dielectric layer to resist a thermal stress. Further, the formation of the conductive pillar 41 can prevent a high aspect ratio of an opening of the lowest dielectric layer, which is configured to accommodate a conductive via. As a result, the conductive via 51v may have a relatively small aspect ratio, which improves the yield of manufacturing the package structure 1a.

In the embodiment illustrated in FIG. 1, an interface 10s3 may be formed between the encapsulant 70 and the electronic component 10. The dielectric layer 31 may cover the encapsulant 70, the electronic component 10 and the interface. Thus, the dielectric layer 31 may be configured to reduce a delamination between the dielectric layer 31 and the electronic component 10 and between the encapsulant 70 and the electronic component 10 near the interface 10s3. Alternatively, the dielectric layer 31 may be configured to release a stress occurring near the interface 10s3 due to CTE mismatch between the encapsulant 70 and the electronic component 10.

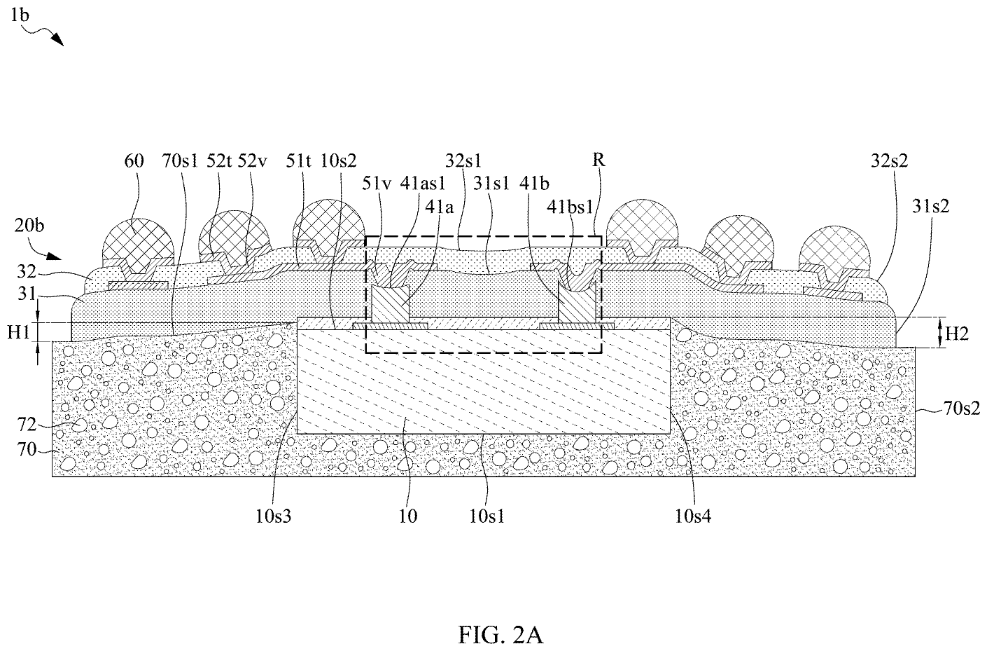

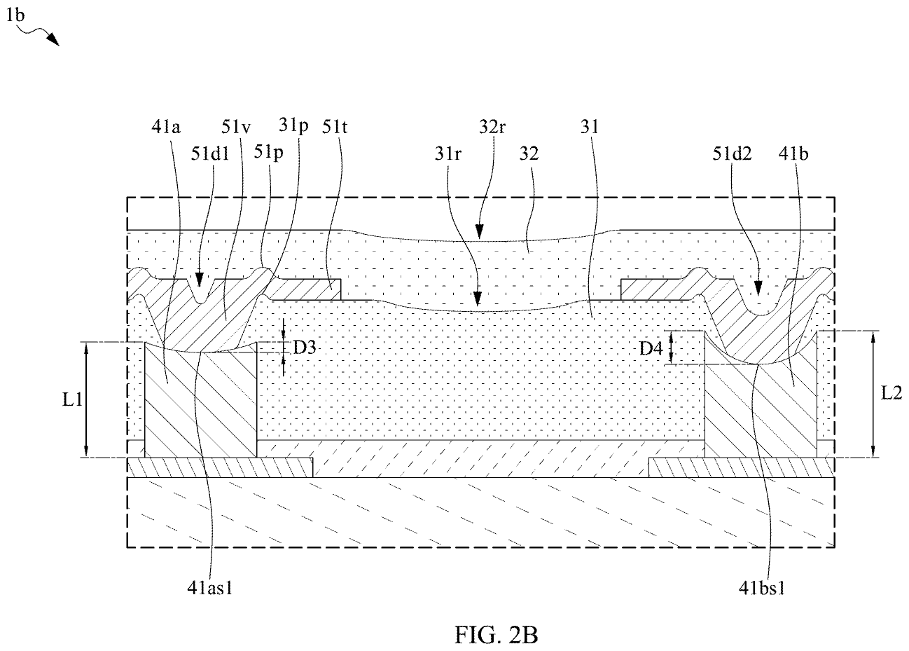

FIG. 2A illustrates a cross-sectional view of an example of a package structure 1b according to some embodiments of the present disclosure. The package structure 1b is similar to the package structure 1a as shown in FIG. 1, and the differences therebetween are described below.

In some embodiments, the encapsulant 70 may have an uneven roughness. In some embodiments, the encapsulant 70 may have a smaller roughness at the surface 10s3 (or a side) of the electronic component 10 and a greater roughness at a surface 10s4 (or a side) of the electronic component 10. For example, the encapsulant 70 may have a smaller height difference H1 between the lowest point and the highest point at the surface 10s3 of the electronic component 10 and a greater height difference H2 between the lowest point and the highest point at the surface 10s4 of the electronic component 10. In some embodiments, a portion of the surface 10s3 of the electronic component 10 may be exposed from the encapsulant 70, and the surface 10s4 of the electronic component 10 may be completely covered by the encapsulant 70.

The package structure 1b may have a redistribution structure 20b different from the redistribution structure 20a. In some embodiments, a surface 31s2 (or a lateral surface or an edge) of the dielectric layer 31 may be not aligned with a surface 70s2 (or a lateral surface or an edge) of the encapsulant 70. In some embodiments, the surface (or edge) 70s2 of the encapsulant 70 may exceed the surface (or edge) 31s2 of the dielectric layer 31. In some embodiments, the surface 31s2 of the dielectric layer 31 may be not aligned with a surface 32s2 (or a lateral surface or an edge) of the dielectric layer 32. In some embodiments, the surface 31s2 of the dielectric layer 31 may exceed the surface 32s2 of the dielectric layer 32. The redistribution structure 20b may be tapered along a direction far away from the electronic component 10.

Referring to FIG. 2B, FIG. 2B illustrates a partial enlarged view of the region R of the package structure 1b as shown in FIG. 2A. The package structure 1b may include a conductive pillar 41a and a conductive pillar 41b spaced apart from the conductive pillar 41a by the dielectric layer 31. In some embodiments, the conductive pillar 41a and the conductive pillar 41b may have different dimensions. The conductive pillar 41a may have a depth (or a length or a thickness) L1 between the highest point and the lowest point. The conductive pillar 41b may have a depth (or a length or a thickness) L2 between the highest point and the lowest point. In some embodiments, the depth L2 may be greater than the depth L1. In some embodiments, a surface 41as1 (or an upper surface) of the conductive pillar 41 may have a curvature different from that of a surface 41bs1 (or an upper surface) of the conductive pillar 41b. In some embodiments, a dimple depth D3 of the concave portion (e.g., 41as1) of the conductive pillar 41a may be different from a dimple depth D4 of the concave portion (e.g., 41bs1) of the conductive pillar 41b. In some embodiments, the thickness T1 of the dielectric layer 31 is greater than the depth L1 of the conductive pillar 41.

In some embodiments, the surface 31s1 of the dielectric layer 31 may have a recess 31r between the conductive pillars 41a and 41b. In some embodiments, the surface 31s2 of the dielectric layer 32 may have a recess 32r between the conductive pillars 41a and 41b. The recess 32r may be located over the recess 31r. In some embodiments, the dielectric layer 31 may have a protruded portion 31p adjacent to or over the conductive pillar 41a (or conductive pillar 41b). The protruded portion 31p may have an elevation higher than that of the recess 31r. In some embodiments, the circuit layer 51t (or conductive via 51v) may have a dimple 51d1 over the concave portion (e.g., 41as1) of the conductive pillar 41a. In some embodiments, the circuit layer 51t (or conductive via 51v) may have a dimple 51d2 over the conductive pillar 41b. In some embodiments, the dimple 51d1 may have a curvature different a curvature of the dimple 51d2. In some embodiments, the bottom of the dimple 51d1 may be higher than the bottom of the dimple 51d2. In some embodiments, the circuit layer 51t may have a protruded portion 51p over the protruded portion 31p. The protruded portion 51p may surround the dimple 51d1. In some embodiments, the curvature of the dimple 51d1 may be greater than the curvature of the surface 41as1 of the conductive pillar 41a. In some embodiments, the top of one of the electrical connectors 60 may be located at an elevation different from an elevation of the top of another electrical connectors 60. In some embodiments, one of the electrical connectors 60 may be slanted with respect to the surface 10s2 of the electronic component 10.

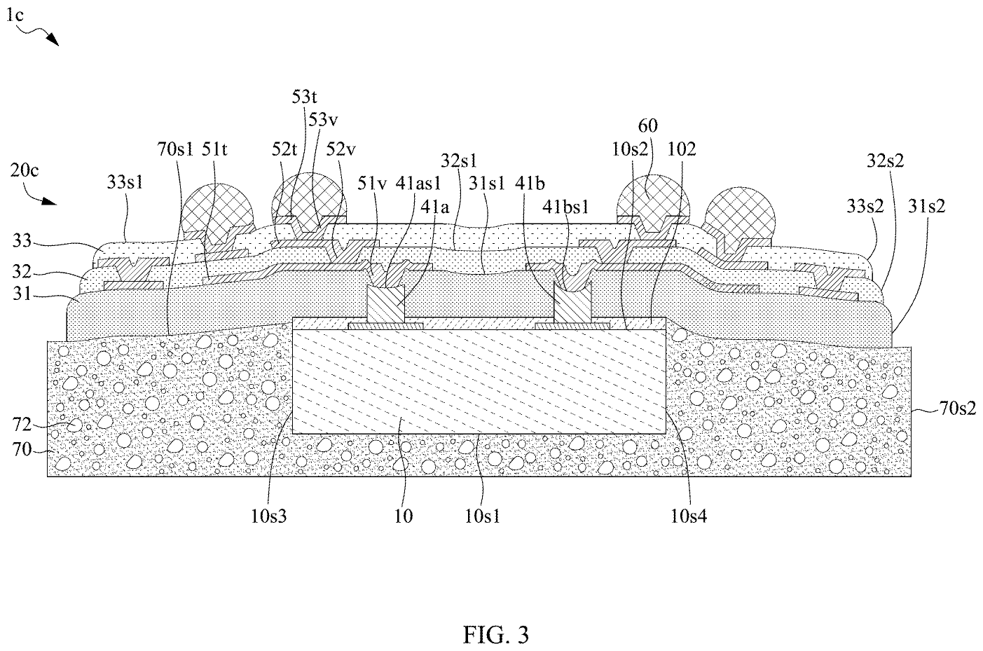

FIG. 3 illustrates a cross-sectional view of an example of a package structure 1c according to some embodiments of the present disclosure. The package structure 1c is similar to the package structure 1a as shown in FIG. 2A, and the differences therebetween are described below.

The package structure 1c may have a redistribution structure 20c different from the redistribution structure 20b. In some embodiments, the package structure 1c may include a dielectric layer 33, a circuit layer 53t, and a conductive via 53v. The dielectric layer 33 may be disposed over the surface 32s1 of the dielectric layer 32. The dielectric layer 33 may cover the circuit layer 52t. In some embodiments, the dielectric layer 33 may be in contact with the dielectric layer 32. The dielectric layer 33 may include, for example, a polyimide or other dielectric suitable materials. The dielectric layer 33 may define openings exposing the circuit layer 52t. Each of the openings of the dielectric layer 33 may be configured to accommodate the conductive via 53v. The dielectric layer 33 may have a surface 33s1 (or an upper surface) and a surface 33s2 (or a lateral surface or a side). In some embodiments, the surface 33s2 may not be aligned with the surface 32s2. In some embodiments, the surface 32s2 may exceed the surface 33s2.

In some embodiments, the conductive via 53v may be disposed over and connected to the circuit layer 52t. In some embodiments, the conductive via 53v may be conformally formed within the opening of the dielectric layer 33.

The circuit layer 53t may be disposed over the surface 33s1 of the dielectric layer 33. The circuit layer 53t may be connected to the conductive via 53v. In some embodiments, the conductive via 53v and the circuit layer 53t may be a monolithic structure, which may be formed by the same process, such as the same deposition process. The circuit layer 53t and the conductive via 53v may collectively function as a UBM.

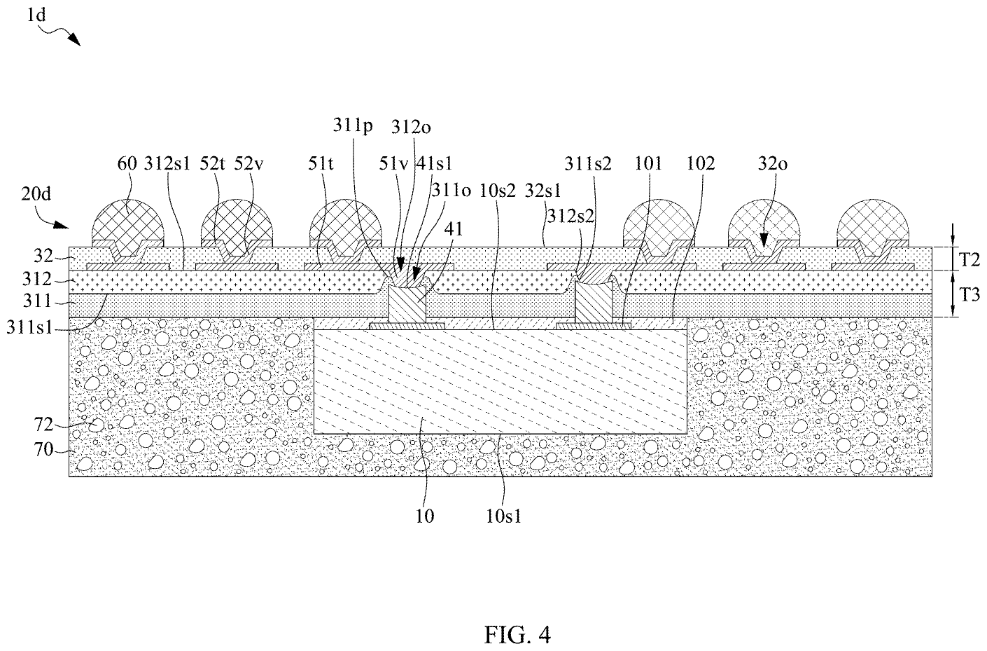

FIG. 4 illustrates a cross-sectional view of an example of a package structure 1d according to some embodiments of the present disclosure. The package structure 1d is similar to the package structure 1a as shown in FIG. 1, and the differences therebetween are described below.

The package structure 1d may have a redistribution structure 20d different from the redistribution structure 20a. The redistribution structure 20d may include a plurality of dielectric layers between the circuit layer 51t and the electronic component 10. For example, the redistribution structure 20d may include a dielectric layer 311 and a dielectric layer 312 over the dielectric layer 311. The dielectric layer 311 may be disposed over the surface 10s2 of the electronic component 10. The dielectric layer 311 may be disposed over the encapsulant 70. In some embodiments, the dielectric layer 311 may be in contact with the passivation layer 102. In some embodiments, the dielectric layer 311 may be in contact with an interface between the encapsulant 70 and the passivation layer 102. The dielectric layer 311 may include, for example, a polyimide or other dielectric suitable materials. The dielectric layer 311 may define openings 311o. The dielectric layer 311 may have a surface 311s1 (or an upper surface or an inner surface) spaced apart from the electronic component 10. The dielectric layer 311 may have a surface 311s2 (or a lateral surface or an inner surface) defining the opening 311o. In some embodiments, the dielectric layer 311 may have a protruded portion 311p over the edge of the conductive pillar 41. In some embodiments, the dielectric layer 311 may cover a portion of the conductive pillar 41. In some embodiments, a portion of the surface 311s1 of the dielectric layer 311 is lower than the surface 41s1 of the conductive pillar 41.

The dielectric layer 312 may be disposed over the surface 311s1 of the dielectric layer 311. In some embodiments, the dielectric layer 312 may be in contact with the dielectric layer 311. The dielectric layer 312 may include, for example, a polyimide or other dielectric suitable materials. In some embodiments, the material of the dielectric layer 311 may be the same as that of the dielectric layer 312. The dielectric layer 312 may define openings 312o. The dielectric layer 312 may have a surface 312s1 (or an upper surface) spaced apart from the dielectric layer 311. The dielectric layer 312 may have a surface 312s2 (or a lateral surface) defining the opening 312o connected to the opening 311o. In some embodiments, the surface 312s2 of the dielectric layer 312 may be substantially coplanar with the surface 311s2 of the dielectric layer 311. In some embodiments, the conductive via 51v may be located within the openings 311o and 312o.

In some embodiments, the dielectric layers 311 and 312 may collectively have a thickness T3, which is the sum of thicknesses of the dielectric layers 311 and 312, between the surface 312s1 and the lower surface (not annotated) of the dielectric layer 311. In some embodiments, the thickness T3 may be greater than the thickness T2. In some embodiments, the ratio between the thickness T3 and the thickness T2 may be 1.8, 2, 2.2, 2.5, 3, 5, or more.

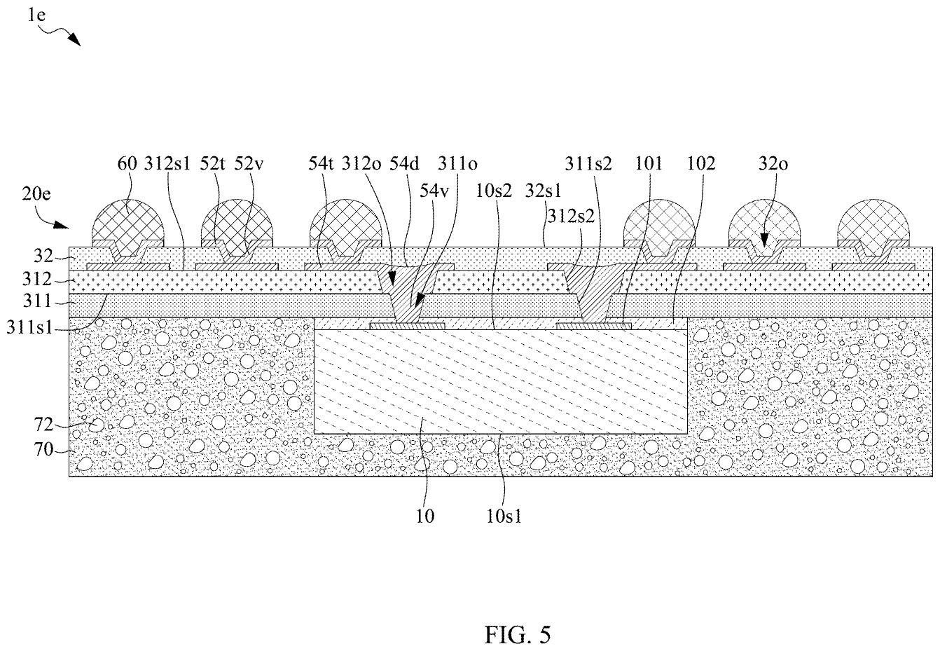

FIG. 5 illustrates a cross-sectional view of an example of a package structure 1e according to some embodiments of the present disclosure. The package structure 1e is similar to the package structure 1d as shown in FIG. 4, and the differences therebetween are described below.

The package structure 1e may have a redistribution structure 20e different from the redistribution structure 20d. In some embodiments, the surface 312s2 may be misaligned with the surface 311s2. In some embodiments, a portion of the surface 311s1 of the dielectric layer 311 may be exposed from the opening 312o. In some embodiments, the material of the dielectric layer 311 may be different from that of the dielectric layer 312.

In some embodiments, the redistribution structure 20e may include a circuit layer 54t and a conductive via 54v. In some embodiments, the conductive via 54v may be located within the openings 311o and 312o. The conductive via 54v may be electrically connected to the terminal 101 of the electronic component 10. The circuit layer 54t may be disposed over the surface 312s1 of the dielectric layer 312. The circuit layer 54t may be connected to the conductive via 54v. In some embodiments, the conductive via 54v and the circuit layer 54t may be a monolithic structure. In some embodiments, the circuit layer 54t (or conductive via 54v) may have a dimple 54d over the opening 312o.

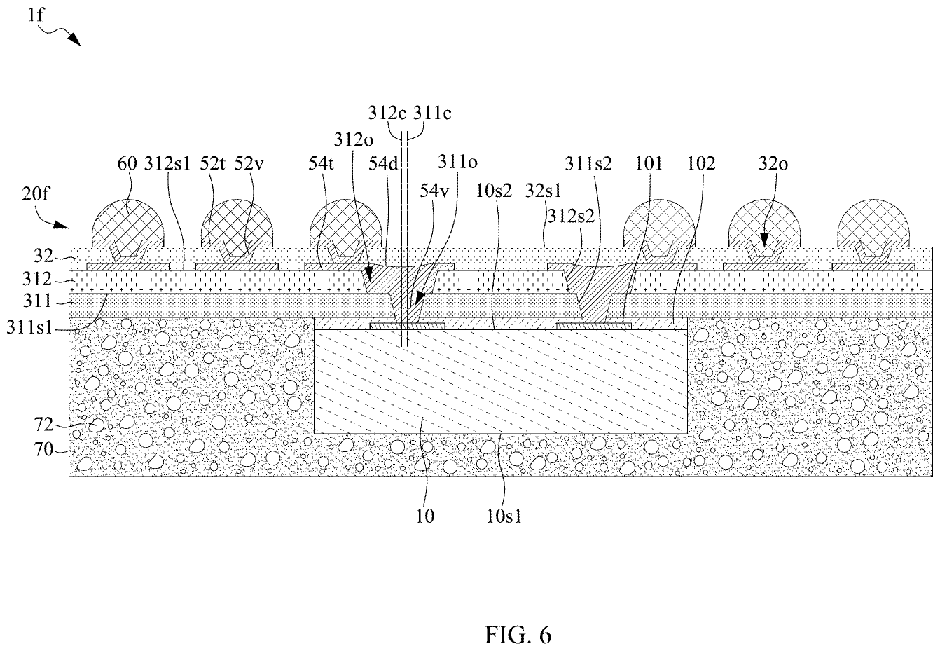

FIG. 6 illustrates a cross-sectional view of an example of a package structure 1f according to some embodiments of the present disclosure. The package structure 1f is similar to the package structure 1e as shown in FIG. 5, and the differences therebetween are described below.

The package structure 1f may have a redistribution structure 20f different from the redistribution structure 20e. The opening 311o may have a center axis 311c. The opening 312o may have a center axis 312c. In some embodiments, the center axis 311c may be shifted from the center axis 312c. For example, the center of the opening 311o may be misaligned with the center of the opening 312o.

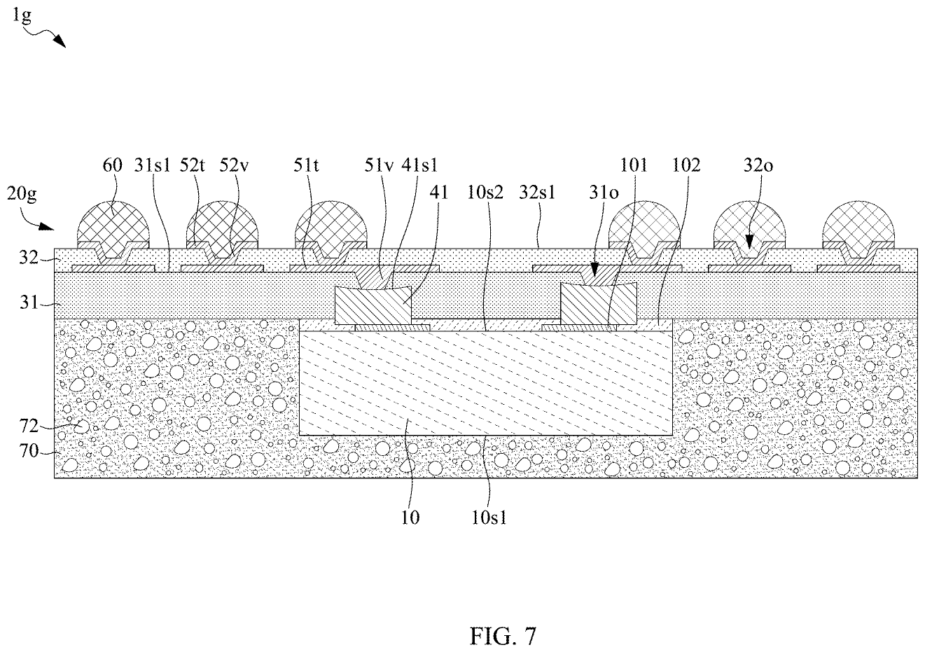

FIG. 7 illustrates a cross-sectional view of an example of a package structure 1g according to some embodiments of the present disclosure. The package structure 1g is similar to the package structure 1a as shown in FIG. 1, and the differences therebetween are described below.

The package structure 1g may have a redistribution structure 20g different from the redistribution structure 20a. In some embodiments, the conductive pillar 41 may be misaligned with the terminal 101 of the electronic component 10. In some embodiments, the conductive pillar 41 may have an edge exceeding an edge of the terminal 101 of the electronic component 10.

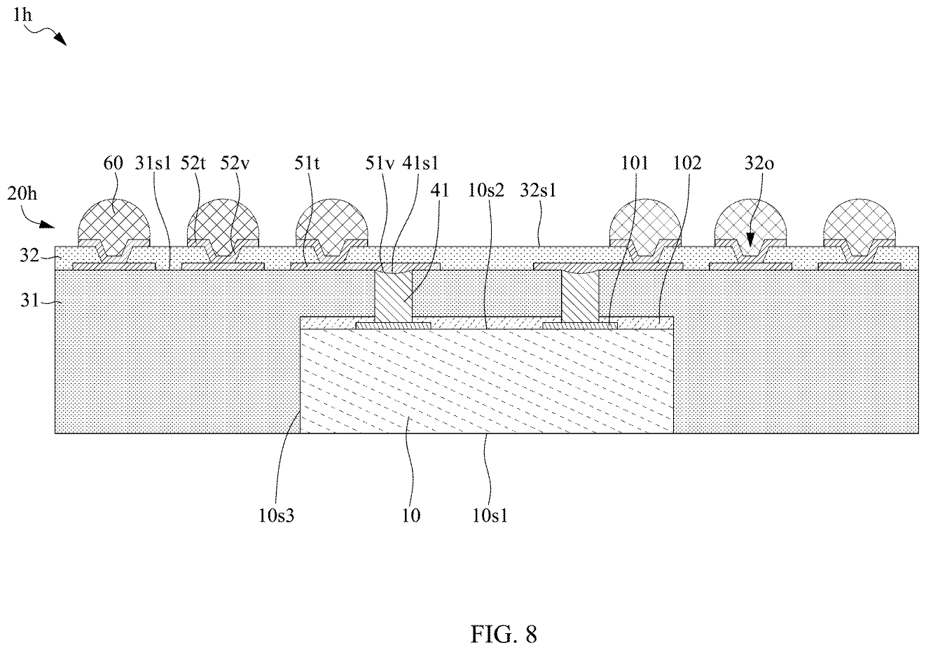

FIG. 8 illustrates a cross-sectional view of an example of a package structure 1h according to some embodiments of the present disclosure. The package structure 1h is similar to the package structure 1a as shown in FIG. 1, and the differences therebetween are described below.

The package structure 1h may have a redistribution structure 20h different from the redistribution structure 20a. In some embodiments, the edge of the conductive pillar 41 may be located an elevation the same as that of the surface 31s1 of the dielectric layer 31. In some embodiments, the edge of the conductive pillar 41 may have a depth (or a length) the same as the thickness T1, as annotated in FIG. 1, of the dielectric layer 31. In some embodiments, the dielectric layer 31 may encapsulate the electronic component 10. In some embodiments, the dielectric layer 31 may cover the surface 10s3 of the electronic component 10. In this embodiment, an encapsulant (e.g., the encapsulant 70 as shown in FIG. 1) may be omitted.

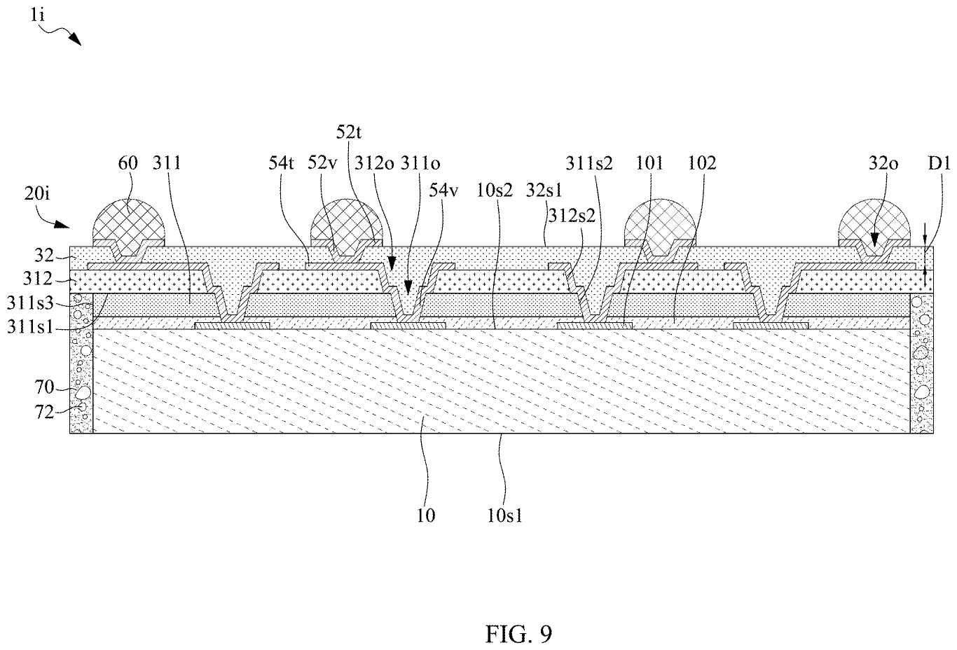

FIG. 9 illustrates a cross-sectional view of an example of a package structure 1i according to some embodiments of the present disclosure. The package structure 1i is similar to the package structure 1e as shown in FIG. 5, and the differences therebetween are described below.

The package structure 1i may have a redistribution structure 20i different from the redistribution structure 20e. In some embodiments, the conductive via 54v may be conformally disposed over the surface 311s2 and surface 312s2. In some embodiments, the conductive via 54v may be conformally disposed within the openings 311o and 312o. In some embodiments, a portion of the dielectric layer 32 may be located within the opening 311o of the dielectric layer 311. In some embodiments, a portion of the dielectric layer 32 may be located within the opening 312o of the dielectric layer 312. In some embodiments, the encapsulant 70 may cover a surface 311s3 (or a lateral surface or an edge) of the dielectric layer 311. The encapsulant 70 may be in contact with the dielectric layer 312.

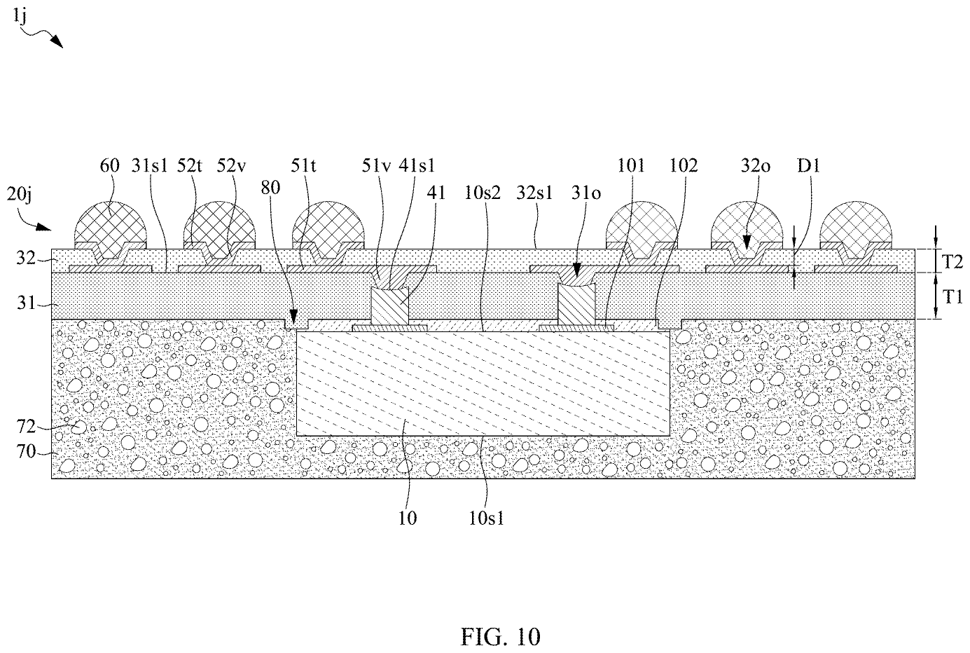

FIG. 10 illustrates a cross-sectional view of an example of a package structure 1j according to some embodiments of the present disclosure. The package structure 1j is similar to the package structure 1a as shown in FIG. 1, and the differences therebetween are described below.

The package structure 1j may have a redistribution structure 20j different from the redistribution structure 20a. In some embodiments, the package structure 1j may have a recess 80. The recess 80 may be recessed from the surface 70s1 of the encapsulant 70. The recess 80 may be recessed from the upper surface of the passivation layer 102. In some embodiments, a portion of the dielectric layer 31 may fill the recess 80. In some embodiments, a portion of the dielectric layer 31 may be in contact with the lateral surface of the passivation layer 102.

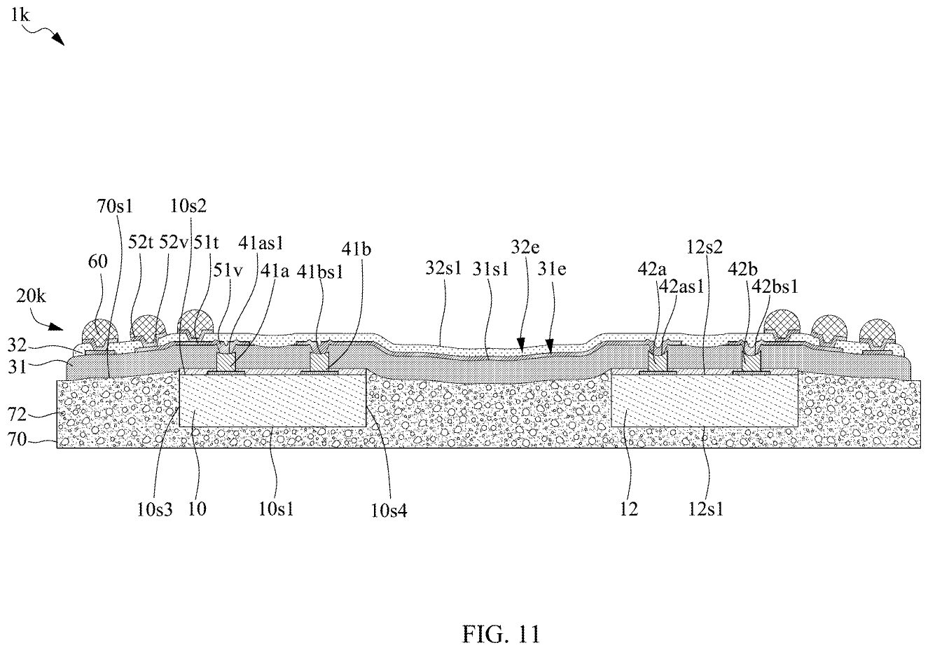

FIG. 11 illustrates a cross-sectional view of an example of a package structure 1k according to some embodiments of the present disclosure. The package structure 1k is similar to the package structure 1b as shown in FIG. 2A, and the differences therebetween are described below.

In some embodiments, the package structure 1k may include an electronic component 12 and a redistribution structure 20k.

The electronic component 12 may be spaced apart from the electronic component 10. The electronic component 12 may be encapsulated by the encapsulant 70. Thus, the encapsulant 70 may encapsulate the electronic component 10 and the electronic component 12. The electronic component 12 may be electrically connected to the electronic component 10 by the circuit layer 51t. The electronic component 12 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 12 may include a system on chip (SoC). For example, the electronic component 12 may include a radiofrequency IC (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. The electronic component 12 may have a surface 12s1 (or a lower surface) and a surface 12s2 (or an upper surface) opposite to the surface 12s1. The surface 12s1 may function as a backside surface. The surface 12s2 may function as an active surface through which a signal or a power pass.

The redistribution structure 20k may include a conductive pillar 42a and a conductive pillar 42b. Each of the conductive pillars 42a and 42b may be electrically connected to the electronic component 12. The conductive pillars 42a and 42b may be disposed over the surface 12s2 of the electronic component 10. The conductive pillars 42a and 42b may include, for example, copper, aluminum, titanium, another conductive metal, or an alloy thereof. The conductive pillar 42a may have a surface 42as1 (or an upper surface). In some embodiments, the surface 42as1 may be a concave surface (or a concave portion). The conductive pillar 42b may have a surface 42bs1 (or an upper surface). In some embodiments, the surface 42bs1 may be a concave surface (or a concave portion). In some embodiments, the curvature of the surface 41as1 of the conductive pillar 41a may be different from the curvature of the surface 42as1 of the conductive pillar 42. In some embodiments, a depth (or a length or a thickness) of the conductive pillar 41a may be different from a depth (or a length or a thickness) of the conductive pillar 42a. In some embodiments, a dimple depth of the concave portion 41as1 of the conductive pillar 41a may be different from a dimple depth of the concave portion 42as1 of the conductive pillar 42a. In some embodiments, a depth (or a length or a thickness) of the concave portion of the conductive pillar 41a may be different from a depth (or a length or a thickness) of the concave portion of the conductive pillar 42b.

In some embodiments, the dielectric layer 31 may be disposed over the encapsulant 70 and may expose the surface 10s2 of the electronic component 10 and the surface 12s2 of the electronic component 12. In some embodiments, the dielectric layer 31 may include a concave portion (or recess) 31e between the electronic component 10 and electronic component 12. In some embodiments, the dielectric layer 32 may include a concave portion (or recess) 32e between the electronic component 10 and electronic component 12. The concave portion (or recess) 32e may be located over the concave portion (or recess) 31e.

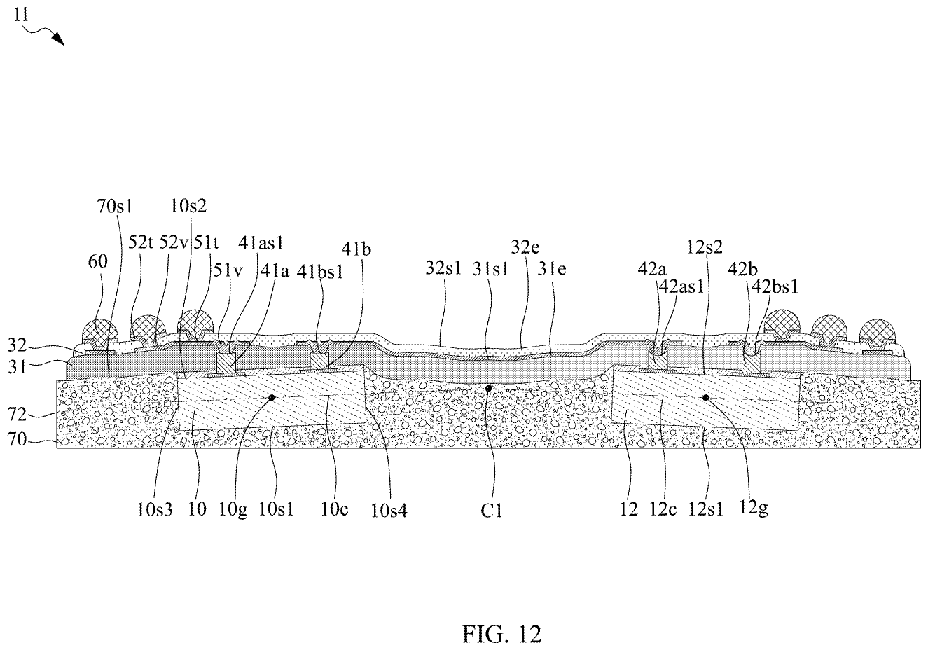

FIG. 12 illustrates a cross-sectional view of an example of a package structure 1l according to some embodiments of the present disclosure. The package structure 1l is similar to the package structure 1k as shown in FIG. 11, and the differences therebetween are described below.

In some embodiments, the surface 10s2 of the electronic component 10 may be nonparallel to the surface 12s2 of the electronic component 12. In some embodiments, the electronic component 10 may include a horizontal axis 10c passing through the geometry center 10g of the electronic component 10. In some embodiments, the electronic component 12 may include a horizontal axis 12c passing through the geometry center 12g of the electronic component 12. In some embodiments, the horizontal axes 10c and 12c may intersect at the point C1 which is higher than the geometry center 10g (or geometry center 12g).

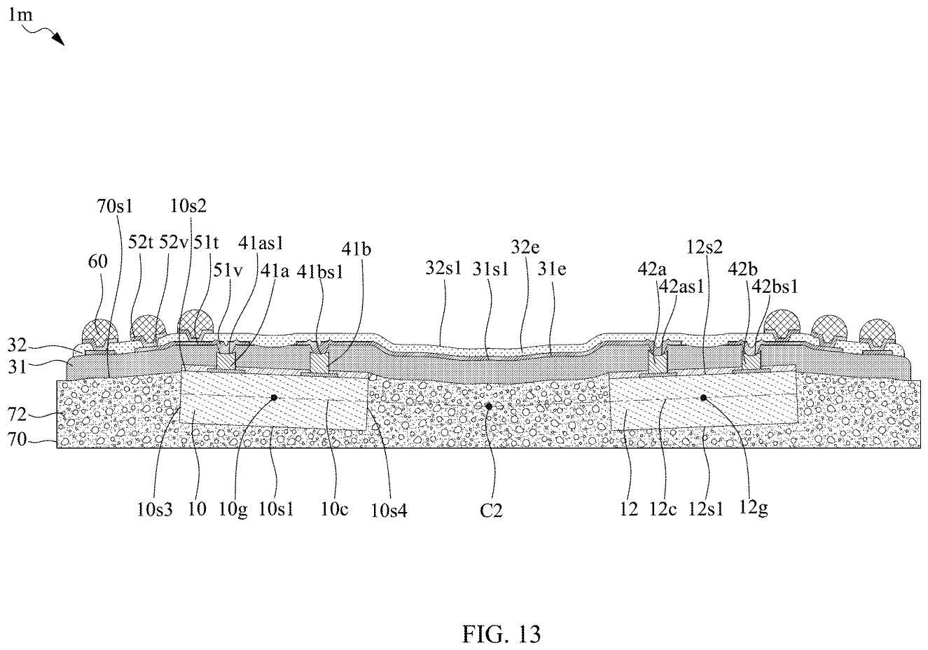

FIG. 13 illustrates a cross-sectional view of an example of a package structure 1m according to some embodiments of the present disclosure. The package structure 1m is similar to the package structure 1k as shown in FIG. 11, and the differences therebetween are described below.

In some embodiments, the horizontal axes 10c and 12c may intersect at the point C2 which is lower than the geometry center 10g (or geometry center 12g).

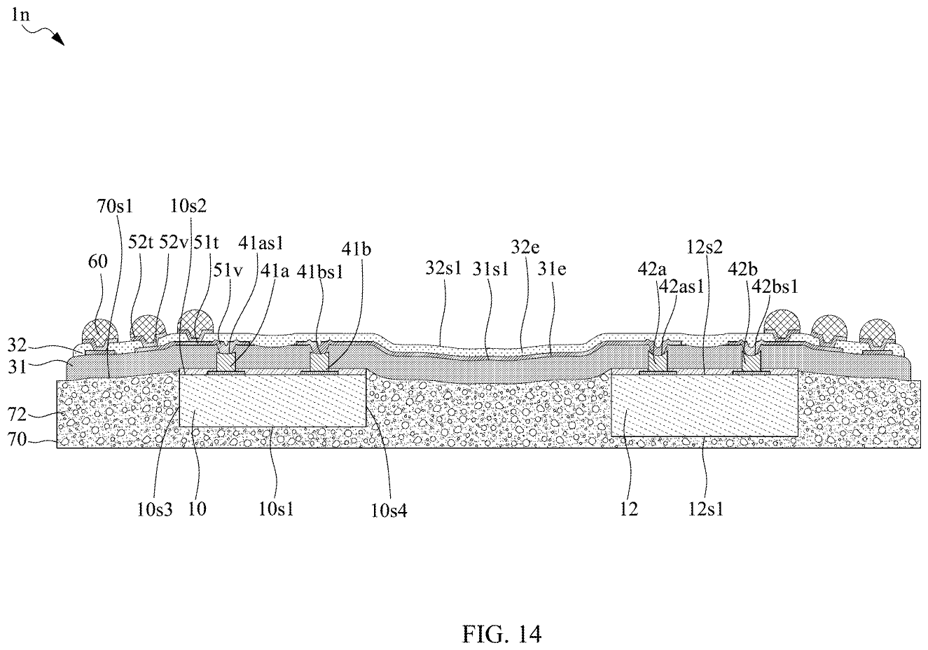

FIG. 14 illustrates a cross-sectional view of an example of a package structure 1n according to some embodiments of the present disclosure. The package structure 1n is similar to the package structure 1k as shown in FIG. 11, and the differences therebetween are described below.

In some embodiments, the electronic component 12 may have a dimension different from that of the electronic component 10. For example, the electronic component 12 may have a length (or thickness) greater than a length (or thickness) of the electronic component 10.

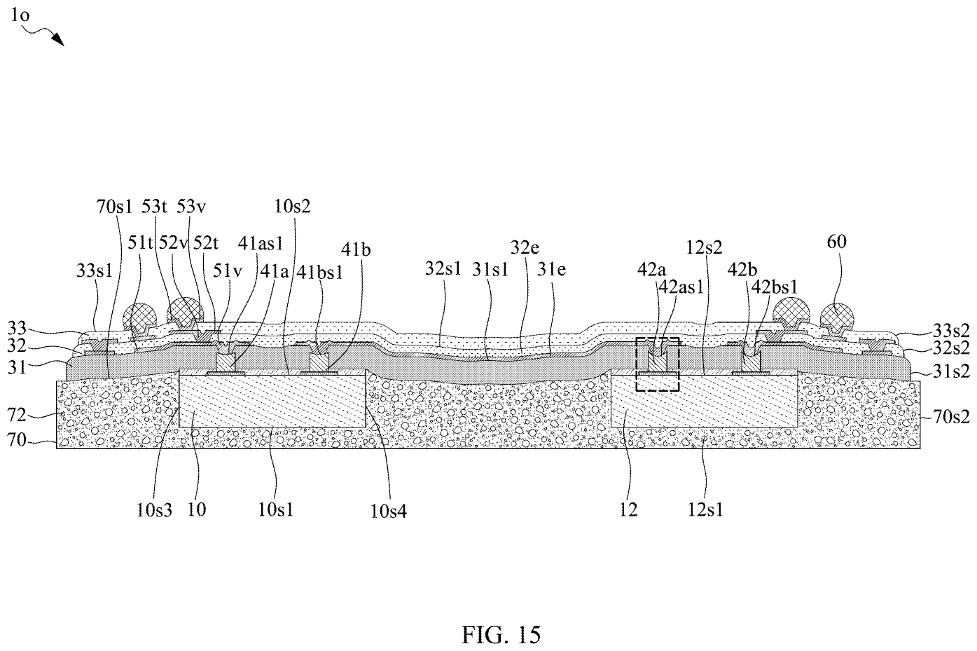

FIG. 15 illustrates a cross-sectional view of an example of a package structure 1o according to some embodiments of the present disclosure. The package structure 1o is similar to the package structure 1k as shown in FIG. 11, and the differences therebetween are described below.

In some embodiments, the package structure 1o may include a dielectric layer 33 over the dielectric layer 32. The package structure 1o may include a conductive via 53v and a circuit layer 53t. In some embodiments, the conductive via 53v may be disposed over and connected to the circuit layer 52t. The circuit layer 53t may be disposed over the surface 33s1 of the dielectric layer 33.

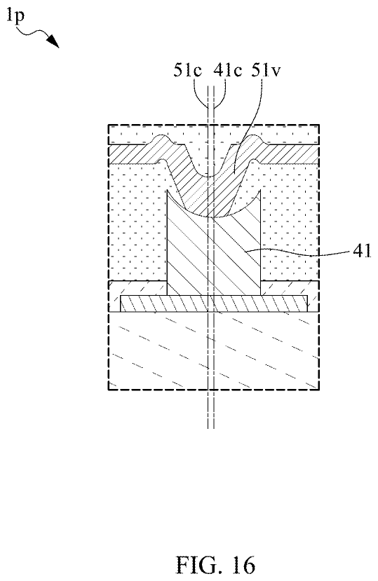

FIG. 16 illustrates a cross-sectional view of an example of a package structure 1p according to some embodiments of the present disclosure. The conductive pillar 41 may have a center axis 41c. The conductive via 51v may have a center axis 51c. In some embodiments, the center axis 41c may be shifted from the center axis 51c. For example, the center axis 51c (or center) of the conductive via 51v may be misaligned with the center axis 41c (or center) of the conductive pillar 41.

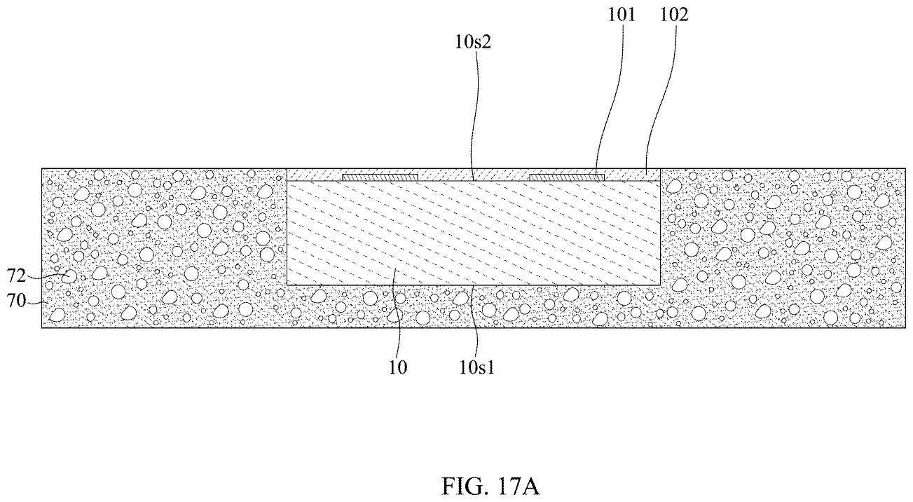

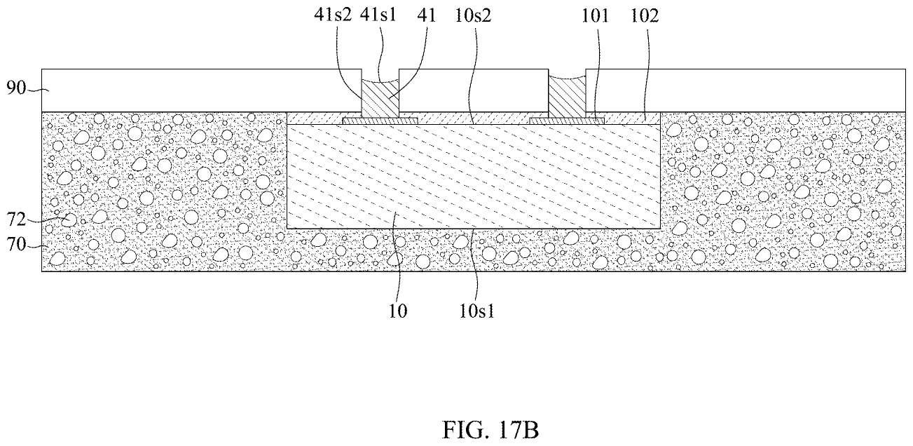

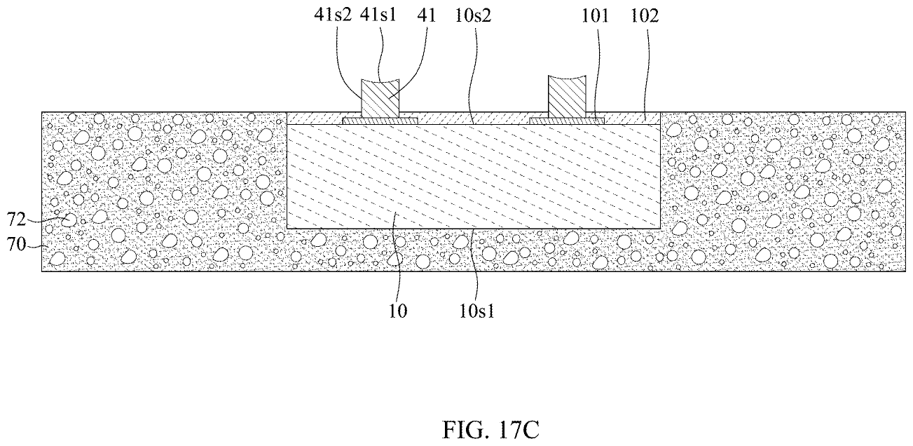

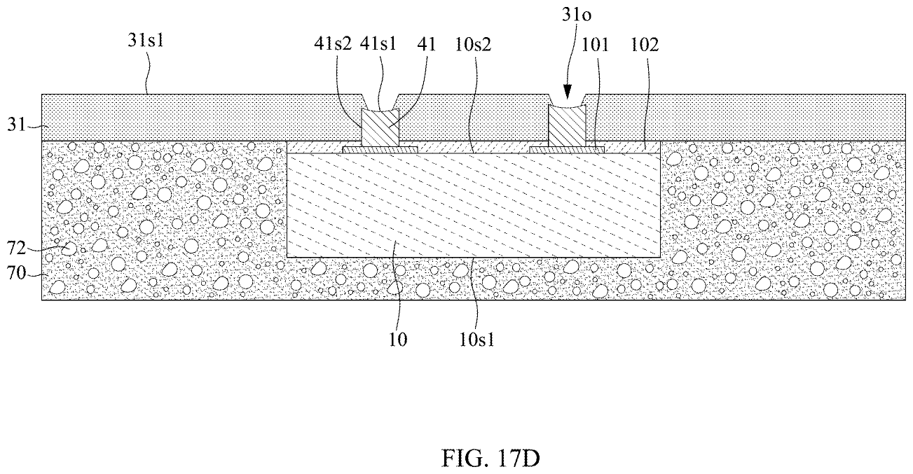

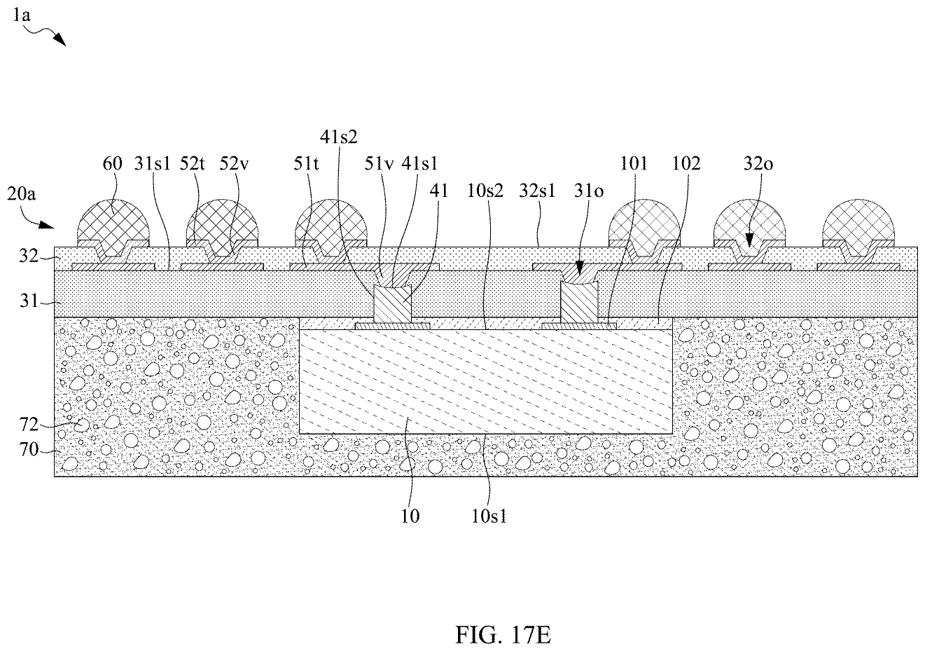

FIG. 17A to FIG. 17E illustrate various stages of an example of a method for manufacturing a package structure according to some embodiments of the present disclosure.

Referring to FIG. 17A, an electronic component 10 may be provided. An encapsulant 70 may be formed to encapsulate the electronic component 10. The surface 10s2 of the electronic component 10 may be exposed from the encapsulant 70.

Referring to FIG. 17B, a mask 90, such as photoresist, may be formed over the surface 70s1 of the encapsulant 70 and over the surface 10s2 of the electronic component 10. The mask 90 may defining openings (not annotated). An etching process may be performed to remove a portion of the passivation layer 102. A conductive pillar 41 may be formed within the opening of the mask 90 and connected to the terminal 101.

Referring to FIG. 17C, the mask 90 may be removed to expose the encapsulant 70.

Referring to FIG. 17D, a dielectric layer 31 may be formed over the encapsulant 70 to cover the conductive pillar 41. In some embodiments, an etching process may be performed to remove a portion of the dielectric layer 31 so that the conductive pillar 41 may be exposed from the dielectric layer 31.

Referring to FIG. 17E, a dielectric layer 32, a circuit layer 51t, conductive via 51v, a circuit layer 52t, a conductive via 52v, and electrical connectors 60 may be formed. As a result, a package structure, such as the package structure 1a as shown in FIG. 1A, may be produced.

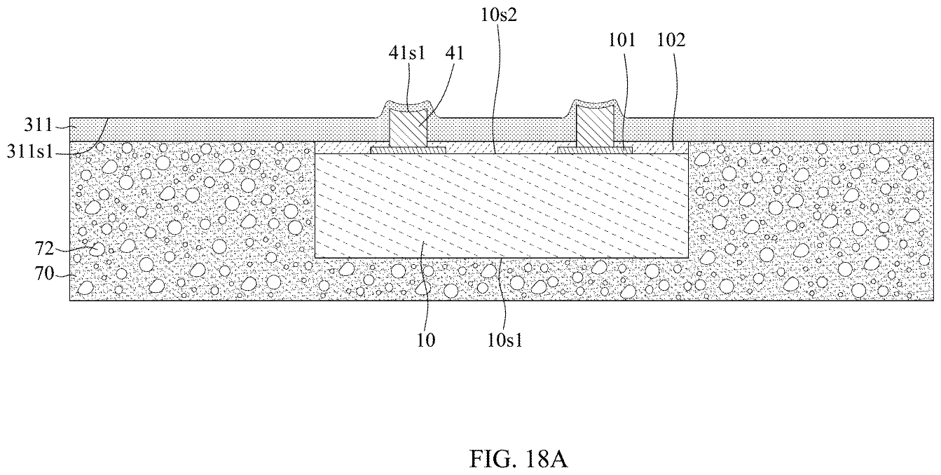

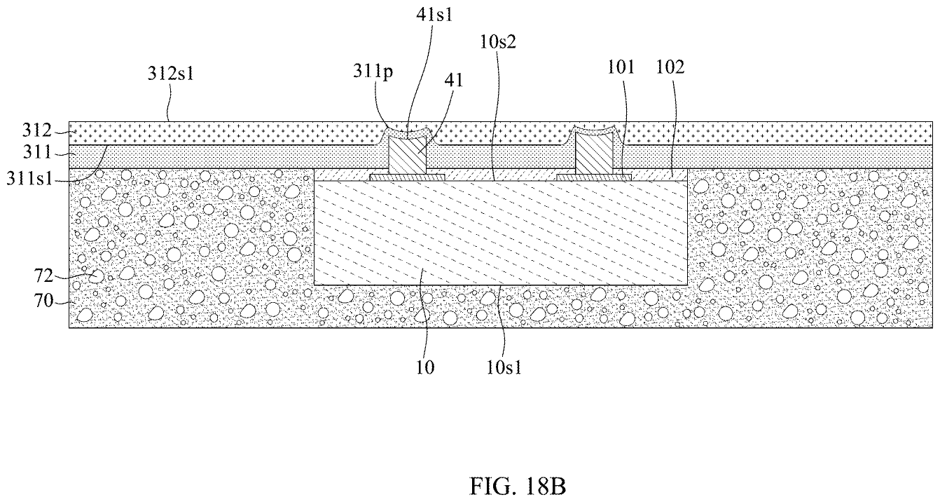

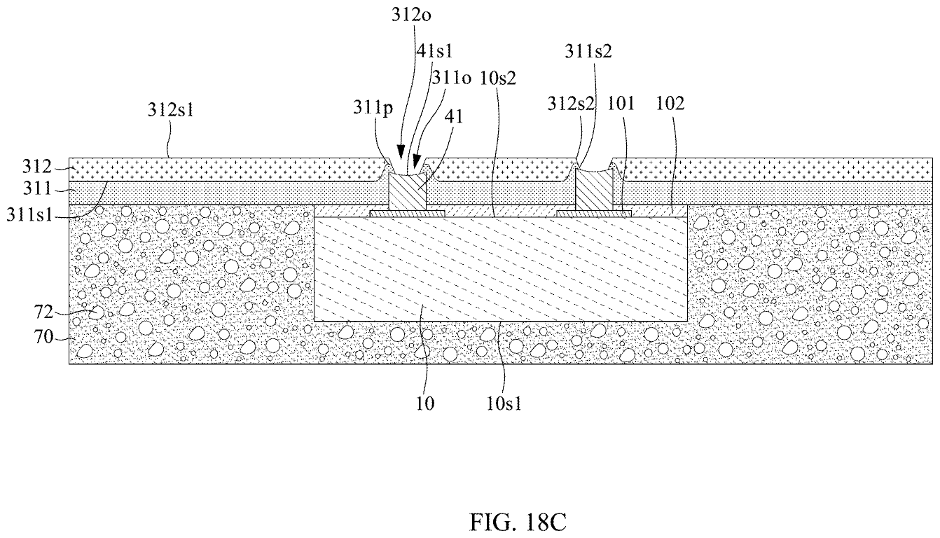

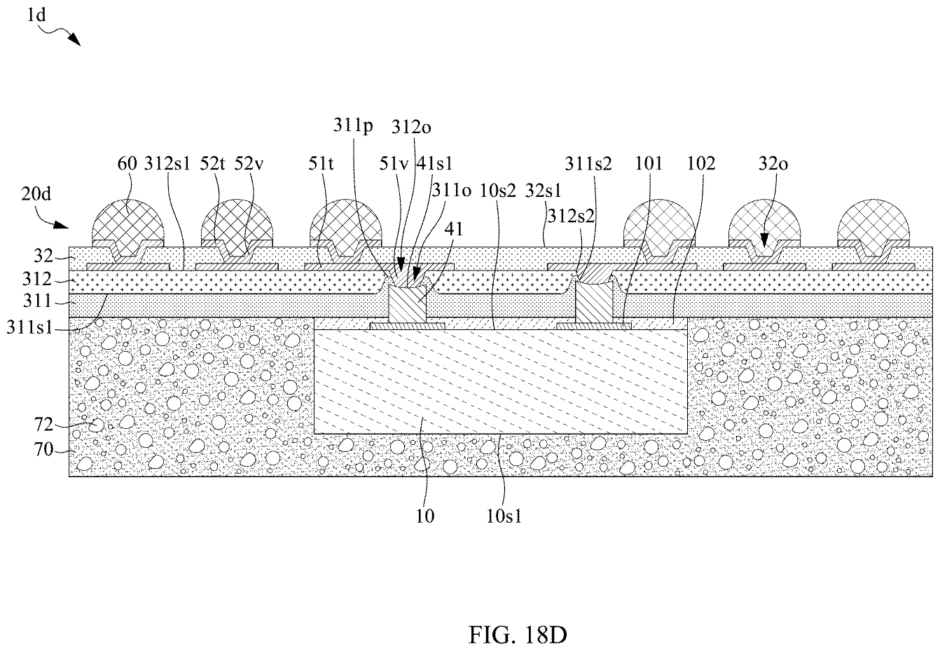

FIG. 18A to FIG. 18D illustrate various stages of an example of a method for manufacturing a package structure according to some embodiments of the present disclosure. The initial stage of the illustrated process is the same as, or similar to, the stage illustrated in FIG. 17A through FIG. 17C. FIG. 18A depicts a stage subsequent to that depicted in FIG. 17C.

Referring to FIG. 18A, a dielectric layer 311 may be formed to cover the surface 10s2 of the electronic component 10, the encapsulant 70, and the conductive pillar 41.

Referring to FIG. 18B, a dielectric layer 312 may be formed on the dielectric layer 311 to cover the dielectric layer 311.

Referring to FIG. 18C, an etching process may be performed to remove a portion of the dielectric layers 311 and 312. As a result, openings 311o and 312o may be formed. The openings 311o and 312o may expose the conductive pillar 41.

Referring to FIG. 18D, a dielectric layer 32, a circuit layer 51t, a conductive via 51v, a circuit layer 52t, a conductive via 52v, and electrical connectors 60 may be formed. As a result, a package structure, such as the package structure 1d as shown in FIG. 4, may be produced.

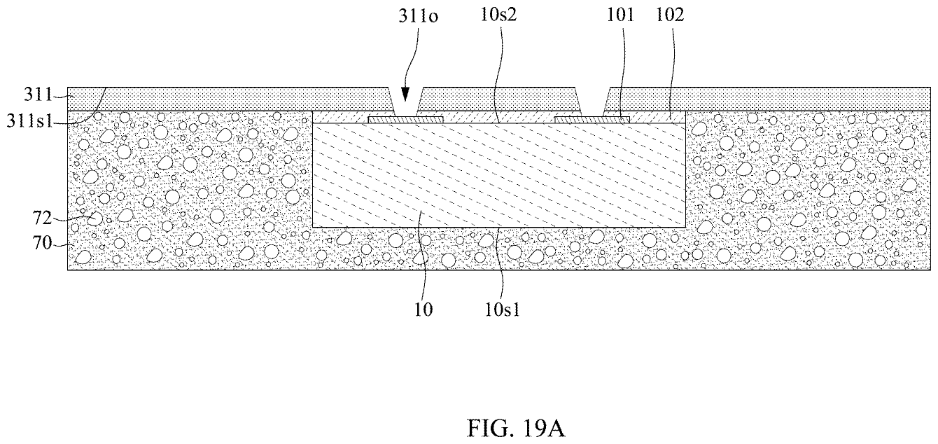

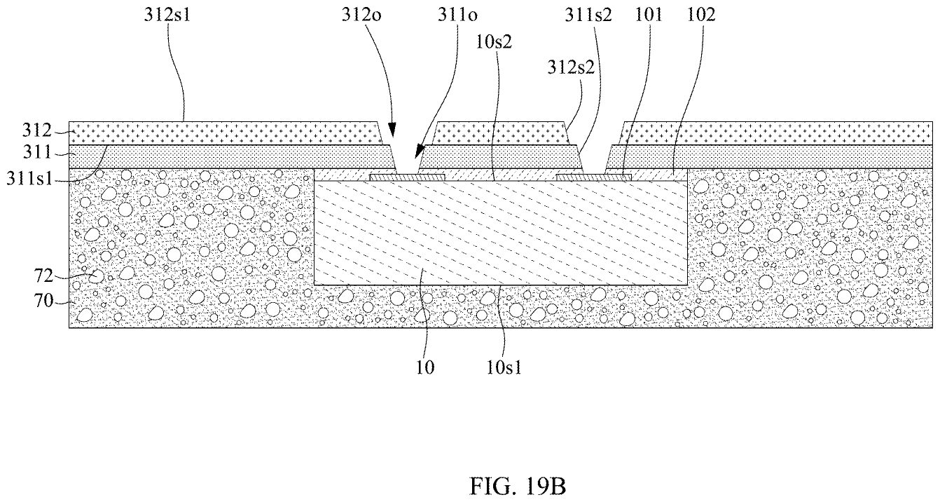

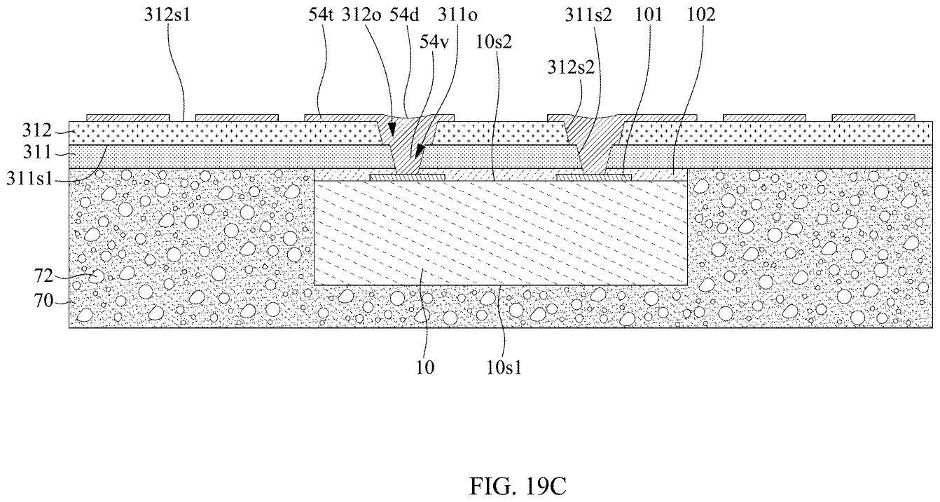

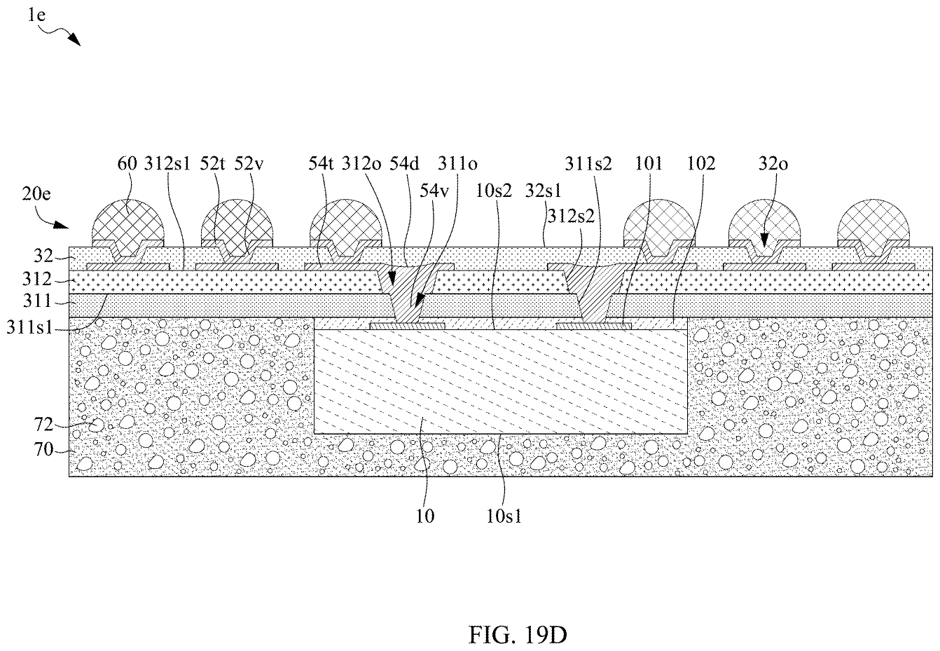

FIG. 19A to FIG. 19D illustrate various stages of an example of a method for manufacturing a package structure according to some embodiments of the present disclosure. FIG. 19A depicts a stage subsequent to that depicted in FIG. 17A.

Referring to FIG. 19A, a dielectric layer 311 may be formed over the surface 10s2 of the electronic component 10 and over the encapsulant 70, and an etching process may be performed to remove a portion of the dielectric layer 311. As a result, openings 311o may be formed to expose the terminal 101.

Referring to FIG. 19B, a dielectric layer 312 may be formed to cover the dielectric layer 311. An etching process may be performed to remove a portion of the dielectric layer 312. As a result, openings 312o may be formed.

Referring to FIG. 19C, a conductive via 54v and a circuit layer 54t may be formed to cover the dielectric layer 312.

Referring to FIG. 19D, a dielectric layer 32, a circuit layer 52t, a conductive via 52v, and electrical connectors 60 may be formed. As a result, a package structure, such as the package structure 1e as shown in FIG. 5, may be produced.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of arrangements of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to =0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to #1°, less than or equal to ±0.5°, less than or equal to ±0.1°, or less than or equal to ±0.05°.

Two surfaces can be deemed to be coplanar or substantially coplanar if a displacement between the two surfaces is no exceeding 5 μm, no exceeding 2 μm, no exceeding 1 μm, or no exceeding 0.5 μm. A surface can be deemed to be substantially flat if a displacement between the highest point and the lowest point of the surface is no exceeding 5 μm, no exceeding 2 μm, no exceeding 1 μm, or no exceeding 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity exceeding approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
an electronic component having an active surface;
an encapsulant encapsulating the electronic component and exposing the active surface of the electronic component;
a first conductive pillar over the active surface of the electronic component, wherein an upper surface of the first conductive pillar includes a concave portion; and
a first dielectric layer over the encapsulant and the active surface of the electronic component, wherein the first dielectric layer defines an opening exposing the concave portion of the first conductive pillar.

2. The package structure of claim 1, wherein a thickness of the first dielectric layer is greater than a thickness of the first conductive pillar.

3. The package structure of claim 1, wherein the upper surface of the first conductive pillar is closer to an upper surface of the first dielectric layer than to the active surface of the electronic component.

4. The package structure of claim 1, further comprising:
a first conductive via disposed over the first dielectric layer, wherein a thickness of the first dielectric layer is greater than a depth of the first conductive via.

5. The package structure of claim 1, further comprising:
a redistribution structure disposed over the encapsulant and the electronic component and comprising the first dielectric layer and the first conductive pillar, wherein the redistribution structure is tapered along a direction far away from the electronic component.

6. The package structure of claim 1, wherein the first dielectric layer extends into the concave portion of the first conductive pillar.

7. The package structure of claim 5, wherein the redistribution structure further comprises a second conductive via connected to the concave portion of the first conductive pillar, and a portion of the upper surface of the first conductive pillar is higher than a bottom of the second conductive via.

8. The package structure of claim 5, wherein the redistribution structure further comprises a first circuit layer, and the first circuit layer includes a dimple over the concave portion of the first conductive pillar.

9. The package structure of claim 8, wherein the first circuit layer includes a protruded portion surrounding the dimple.

10. The package structure of claim 9, wherein an edge of the encapsulant exceeds an edge of the first dielectric layer.

11. The package structure of claim 1, further comprising:
a second dielectric layer over the first dielectric layer, wherein a thickness of the first dielectric layer is greater than a thickness of the second dielectric layer.

12. The package structure of claim 1, further comprising:
a second conductive pillar over the active surface of the electronic component, wherein a dimple depth of a concave portion of the second conductive pillar is different from a dimple depth of the concave portion of the first conductive pillar.

13. The package structure of claim 1, further comprising:
a second conductive via connected to the concave portion of the first conductive pillar, wherein a center axis of the second conductive via is misaligned with a center axis of the first conductive pillar.

14. A package structure, comprising:
an electronic component having an active surface; and
a redistribution structure over the active surface of the electronic component, wherein the redistribution structure comprises:
a first dielectric layer over the active surface of the electronic component, wherein the first dielectric layer defines an opening;
a conductive pillar under the opening; and
a second dielectric layer over the first dielectric layer,
wherein a first thickness of the first dielectric layer is greater than a second thickness of the second dielectric layer.

15. The package structure of claim 14, wherein an upper surface of the conductive pillar includes a concave portion.

16. The package structure of claim 14, wherein the conductive pillar includes a lateral surface protruding from the active surface of the electronic component, wherein the redistribution structure further comprises a conductive via over the conductive pillar, the conductive via includes a lateral surface extending between an upper surface of the first dielectric layer and an upper surface of the conductive pillar, and the lateral surface of the conductive via is steeper than the lateral surface of the conductive pillar.

17. The package structure of claim 14, wherein the redistribution structure further comprises a conductive via connected to the conductive pillar, wherein the conductive via laterally overlaps a portion of the conductive pillar.

18. A package structure, comprising:
a first electronic component including a first active surface;
a second electronic component including a second active surface;
an encapsulant encapsulating the first electronic component and the second electronic component; and
a first dielectric layer disposed over the encapsulant and exposing the first active surface and the second active surface, wherein the first dielectric layer includes a concave portion between the first electronic component and the second electronic component.

19. The package structure of claim 18, further comprising:
a first conductive pillar over the first active surface of the first electronic component, wherein an upper surface of the first conductive pillar includes a first concave portion; and
a second conductive pillar over the second active surface of the second electronic component, wherein an upper surface of the second conductive pillar includes a second concave portion.

20. The package structure of claim 19, wherein a dimple depth of the first concave portion is different from a dimple depth of the second concave portion.
